(19) United States
(12) Patent Application Publication
(10) Pub. No.: US 2008/0105941 A1
(43) Pub. Date: May 8, 2008

(54) Sensor-type semiconductor package and fabrication

(75) Inventors: Tse-Wen Chang, Taichung (TW); Chang-Yueh Chan, Taichung Hsien (TW); Chih-Ming Huang, Hsinchu Hsein (TW); Cheng-Hsu Hsiao, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/982,514

(22) Filed: Nov. 2, 2007

(30) Foreign Application Priority Data
Nov. 3, 2006 (TW) 095140686

(51) Int. Cl. H01L 31/0203; H01L 21/00

(52) U.S. Cl. 257/433; 438/64; 257/E31.117

(57) ABSTRACT

The invention provides a sensor-type semiconductor package and fabrication method thereof. The fabrication method includes steps of: attaching a sensor chip to a chip carrier; electrically connecting the sensor chip and a chip carrier via a plurality of bonding wires; mounting a light-permeable body to the sensor chip with an adhesive layer as a partition therebetween, wherein the planar size of the light-permeable body is larger than a predefined planar size of the sensor-type semiconductor package to be formed; forming an encapsulant on the chip carrier for encapsulating the sensor chip and the bonding wires with the upper surface of the light-permeable body being exposed from the encapsulant; and cutting through the light-permeable body, the encapsulant and the chip carrier according to the predefined planar size. Accordingly the contacting area between the cut light-permeable body and the cut encapsulant increased and the bonding therebetween is reinforced.

### BACKGROUND OF THE INVENTION

1. Field of the Invention

The present invention relates generally to semiconductor packages and fabrication methods thereof, and more particularly to a sensor-type semiconductor package and fabrication method thereof.

2. Description of Related Art

Conventionally, to obtain an image sensor package, a sensor chip is mounted to a chip carrier and electrically connected to the chip carrier through the bonding wires, then the top surface of the sensor chip is covered by a glass such that image light can be captured by the sensor chip. Thereafter, the obtained image sensor package can be integrated to an external device such as a printed circuit board (PCB) for further being incorporated in various kinds of electronic products such as digital cameras, digital videos, optical mouse, mobile phones and finger print sensors.

U.S. Pat. No. 6,060,340, No. 6,262,479, and No. 6,590,269 disclose a sensor-type semiconductor package, wherein, a dam lattice is formed on a chip carrier for defining a space and a sensor chip is attached and electrically connected to the chip carrier and received in the space defined by the dam lattice, and then a glass is adhered to the dam lattice for enclosing the space. However, as sufficient space needs to be left on the chip carrier for disposing of the dam lattice, this kind of sensor-type semiconductor package is difficult to be reduced further in size.

In view of the above drawback, U.S. Pat. No. 6,995,462 discloses a sensor-type semiconductor package without the dam lattice. As shown in FIG. 1A, it mainly involves adhering a glass 15 on a sensor chip 10 having a sensor area 103 and a plurality of electrode pads 104 on the active surface thereof, allowing the glass 15 to cover and enclose the sensor area 103 through an adhesive layer 14 and for preventing external particles from entering and contaminating the sensor chip 10. Then, the sensor chip 10 is attached to the substrate 11 and electrically connected with the substrate 11 through the bonding wires 12. Subsequently, an encapsulant 16 is formed on the substrate 11 for encapsulating the sensor chip 10 and the bonding wires 12.

However, due to poor adhesion force and variation of the environmental temperature, cracking C is occurred between side edges of the glass 15 and the encapsulant 16, as shown in FIG. 1B. Accordingly, external moisture or particles can enter the sensor chip 10 and adversely affect the lifetime of the product.

Therefore, there is an urgent need providing a sensor-type semiconductor package and fabrication method thereof that can overcome the above-mentioned drawbacks.

### SUMMARY OF THE INVENTION

According to the above drawbacks, an objective of the present invention is to provide a sensor-type semiconductor package and a fabrication method thereof so as to avoid cracking between the light-permeable body and the encapsulant due to poor adhesion and thus prevent external moisture or particles from entering the semiconductor package that adversely degrades the lifetime of the product.

Another objective of the present invention is to provide a sensor-type semiconductor package and fabrication method thereof, which is free from the size limitation resulted from preserving a sufficient area for mounting the dam lattice thereon.

A further objective of the present invention is to provide a sensor-type package and fabrication method thereof without the need of keeping a certain distance between the sensor area and the electrode pads of the sensor chip, thereby increasing the design flexibility while reducing the size of the sensor chip.

In order to attain the above and other objectives, the present invention discloses a fabrication method of a sensor-type semiconductor package, which comprises the steps of: attaching a sensor chip to a chip carrier; electrically connecting the sensor chip to the chip carrier via a plurality of bonding wires; mounting a light-permeable body to the sensor chip with an adhesive layer as a partition therebetween, wherein the planar size of the light-permeable body is larger than the predefined planar size of the sensor-type semiconductor package to be formed; forming an encapsulant on the chip carrier for encapsulating the sensor chip and the bonding wires with the upper surface of the light-permeable body being exposed from the encapsulant; and cutting the light-permeable body, the encapsulant and the chip carrier according to the predefined planar size of the sensor-type semiconductor package so as to make the cut light-permeable body and the sensor-type semiconductor package have the same planar size.

The active surface of the sensor chip of the present invention has a sensor area and a plurality of electrode pads. The sensor area of the sensor chip is covered and sealed by the light-permeable body, which is mounted to the sensor chip with the adhesive layer as a partition therebetween. According to one embodiment, the adhesive layer is disposed between the sensor area and the electrode pads of the sensor chip. Alternatively, the adhesive layer is heated to a melting state for being disposed on the electrode pads and covering all over the end portions of the bonding wires connected to the sensor chip. After the adhesive layer is solidified, the sensor area is covered and sealed by the light-permeable body.

The sensor-type semiconductor package of the present invention can be fabricated in batch-type process by providing a module having a plurality of chip carriers, respectively attaching a plurality of sensor chips to the chip carriers, mounting a light-permeable body to each sensor chip, encapsulating the chip carriers and performing a cutting process to separate the sensor-type packages. In addition, the light-permeable body can be made of such as glass. In batch-type process, a plurality of glasses can be mounted respectively to the sensor chips or a whole piece of glass can be mounted to the sensor chips. In addition, the encapsulant can be filled between the chip carrier and the light-permeable body for encapsulating the sensor chip and the bonding wires by dispensing, wherein the upper surface of the light-permeable body is exposed from the light-permeable body. Alternatively, a molding process can be performed for forming the encapsulant.

According to another embodiment, after the encapsulating process, the light-permeable body can be bevel cut first along the predefined cutting path so as to form bevel edges on the side surfaces of the light-permeable body. Subsequently, a second cutting process is performed at positions of bevel edges of the light-permeable body so as to obtain a desired sensor-type semiconductor package. Such a method not only avoids cracking of the light-permeable body, but also increases lifetime of cutting tools.

Through the above fabrication method, the present invention discloses a sensor-type semiconductor package, comprising: a chip carrier; a sensor chip attached to the chip carrier and electrically connected with the chip carrier via a plurality of bonding wires; a light-permeable body mounted to the sensor chip with an adhesive layer as a partition therebetween; and an encapsulant formed between the chip carrier and the light-permeable body for encapsulating the sensor chip and the bonding wires, wherein an upper surface of the light-permeable body is exposed from the encapsulant and a planar size of the cut light-permeable body is the same as a planar size of the formed sensor-type semiconductor package. The active surface of the sensor chip has a sensor area and a plurality of electrode pads. The sensor area of the sensor chip is covered and sealed by the light-permeable body, which is mounted to the sensor chip with the adhesive layer as a partition therebetween. The adhesive layer can be disposed between the sensor area and the electrode pads of the sensor chip. Alternatively, the adhesive layer can be heated to a melting state for being disposed on the electrode pads and for covering all over the end portions of the bonding wires connected to the sensor chip. After the adhesive layer is solidified, the sensor area is covered and sealed by the light-permeable body.

Further, bevel edges can be formed at the side surfaces of the light-permeable body so as to increase lifetime of cutting tools. A rough structure can be formed on a portion of the light-permeable body corresponding to the encapsulant for increasing the adhesion force between the light-permeable body and the encapsulant.

Therefore, the sensor-type semiconductor package and the fabrication method thereof in the present invention mainly include attaching a sensor chip to a chip carrier and electrically connecting the sensor chip to the chip carrier via a plurality of bonding wires, then mounting a light-permeable body to the sensor chip for proceeding with a subsequent encapsulating process and a cutting process. As the initial planar size of the light-permeable body is larger than the predefined planar size of the sensor-type semiconductor package to be formed, the encapsulant can be completely formed between the chip carrier and the light-permeable body, that is, the contacting area between the light-permeable body and the encapsulant is maximized. Thus, after cutting according to the predefined planar size, the light-permeable body and the encapsulant completely adhered with each other is provided. With the help of the rough structure formed on the light-permeable body at portions being contacted with the encapsulant, the bonding of the light-permeable body can further be reinforced so as to prevent external moisture or particles from entering the package and adversely affecting the lifetime of the products.

Furthermore, the adhesive layer can be disposed between the sensor area and the electrode pads of the sensor chip. Alternatively, the adhesive layer can be heated to a melting state for being disposed on the electrode pads, and for covering all over the end portions of the bonding wires connected to the sensor chip. And after the adhesive layer is solidified, the sensor area can be covered and sealed by the light-permeable body, thus a step for preserving a space between the sensor area and the electrode pads for bounding for mounting the light-permeable body is bypassed in the present application. Such a method can reduce sizes of the sensor chip and the sensor-type semiconductor package, increase chip production, decrease chip cost and increase design flexibility of the sensor chip.

### BRIEF DESCRIPTION OF DRAWINGS

FIGS. 1A and 1B are sectional diagrams showing a sensor-type semiconductor package according to U.S. Pat. No. 6,995,462;

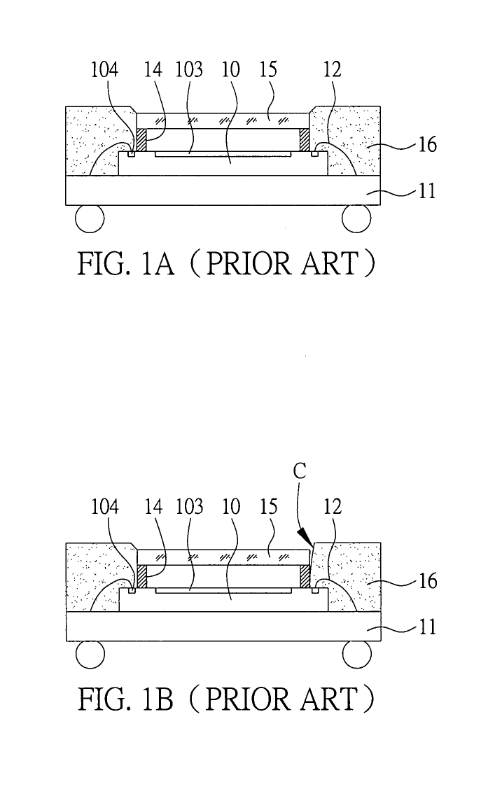

FIGS. 2A to 2D are schematic diagrams showing a sensor-type semiconductor package and fabrication method thereof according to a first embodiment of the present invention;

FIGS. 3A to 3D are schematic diagrams showing a sensor-type semiconductor package and fabrication method thereof according to a second embodiment of the present invention;

FIG. 3B′ is a schematic diagram showing another embodiment of mounting the light-permeable body to the sensor chip according to the present invention;

FIGS. 4A and 4B are schematic diagrams showing a fabrication method of a sensor-type semiconductor package according to a third embodiment of the present invention;

FIG. 4B′ is a schematic diagram showing a molding process for encapsulating the sensor chip according to the present invention;

FIGS. 5A to 5C are schematic cross-sectional diagrams showing a fabrication method of a sensor-type semiconductor package according to a fourth embodiment of the present invention;

FIG. 6 is a schematic cross-sectional diagram of a sensor-type semiconductor package according to a fifth embodiment of the present invention; and

FIG. 7 is a schematic cross-sectional diagram of a sensor-type semiconductor package according to a sixth embodiment of the present invention.

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

### First Embodiment

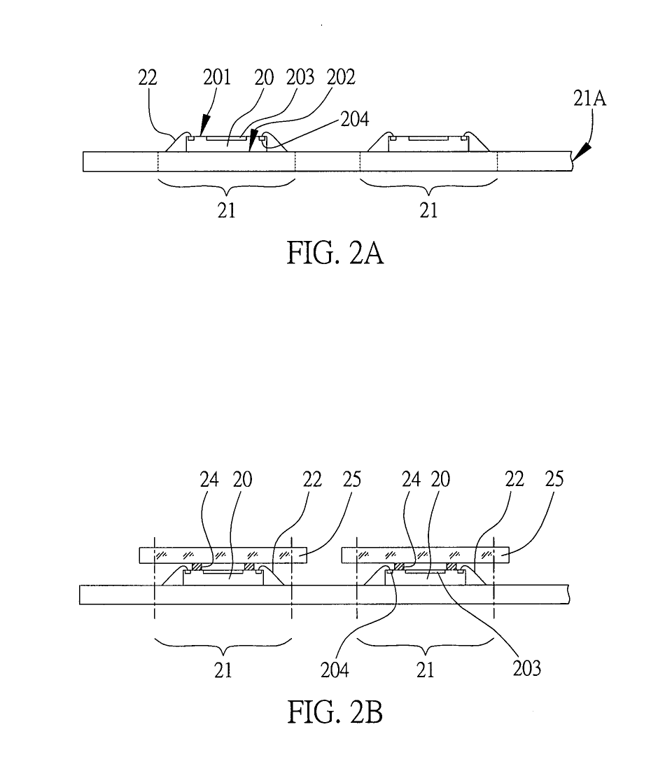

FIGS. 2A to 2D are schematic diagrams showing a sensor-type semiconductor package and fabrication method thereof according to a first embodiment of the present invention. In the present embodiment, the sensor-type package is fabricated in batch-type process for illustration.

As shown in FIG. 2A, a module 21A having a plurality of chip carriers 21 is provided, and a plurality of sensor chips 20 are respectively attached to the chip carriers 21.

Each sensor chip 20 has an active surface 201 and a non-active surface 202 opposed to the active surface 201, and the active surface 201 has a sensor area 203 and a plurality of electrode pads 204 formed thereon. The sensor chip 20 is attached to the chip carrier 21 through its non-active surface 202, and the electrode pads 204 of the sensor chip 20 are connected to the chip carrier 21 via a plurality of bonding wires 22 for electrically coupling the sensor chip 20 and the chip carrier 21. Non-active surfaces 202 of the sensor chips 20 can be thinned first and then the selected good dies are attached to the chip carriers 21. The chip carriers 21 can be such as substrates and leadframes.

As shown in FIG. 2B, light-permeable bodies 25 are respectively mounted to the sensor chips 20 with an adhesive layers 24 as a partition therebetween, wherein the adhesive layers 24 is disposed between the sensor area 203 and the electrode pads 204 of the sensor chip 20, so as to enclose and seal the sensor area 203. The planar size of the light-permeable body 25 is larger than the predefined planar size of the sensor-type semiconductor package to be formed (as defined between the dashed lines).

As shown in FIG. 2C, an encapsulating process is performed so as to form an encapsulant 26 on the chip carriers 21 for encapsulating the sensor chips 20 and the plurality of bonding wires 22, wherein the upper surfaces of the light-permeable bodies 25 are exposed from the encapsulant 26.

As shown in FIG. 2D, the cutting according to the predefined planar size is performed. As the planar size of each light-permeable body 25 is larger than the predefined planar size of the semiconductor package, the cutting path will have to pass through the light-permeable body 25, the encapsulant 26 and the chip carrier 21 to obtain a desired sensor-type semiconductor package 2. After the cutting process, the cut planar size of the light-permeable body 25′ becomes the same as that of the sensor-type semiconductor package 2, that is, the side surfaces of the cut light-permeable body 25′, the cut encapsulant 26′ and the chip carrier 21 are flush with each other, which accordingly maximizes the contacting area between the light-permeable body 25 and the encapsulant 26, thereby reinforcing bonding of the light-permeable body 25.

Through the above fabrication method, the present invention also discloses a sensor-type semiconductor package 2 (as shown in FIG. 2D), which comprises: the chip carrier 21; the sensor chip 20 attached to the chip carrier 21 and electrically connected with the chip carrier 21 via the plurality of bonding wires 22; the light-permeable body 25 mounted on the sensor chip 20 with the adhesive layer 24 as a partition therebetween; and the encapsulant 26 formed between the chip carrier 21 and the light-permeable body 25 for encapsulating the sensor chip 20 and the plurality of bonding wires 22, wherein the upper surface of the light-permeable body 25 is exposed from the encapsulant 26 and the planar size of the cut light-permeable body 25′ is the same as the planar size of the sensor-type semiconductor package 2, that is, the chip carrier 21, the cut light-permeable body 25′ and the cut encapsulant 26′ have the same planar size, thereby making the cut light-permeable body 25′ completely adhered to the cut encapsulant 26′.

### Second Embodiment

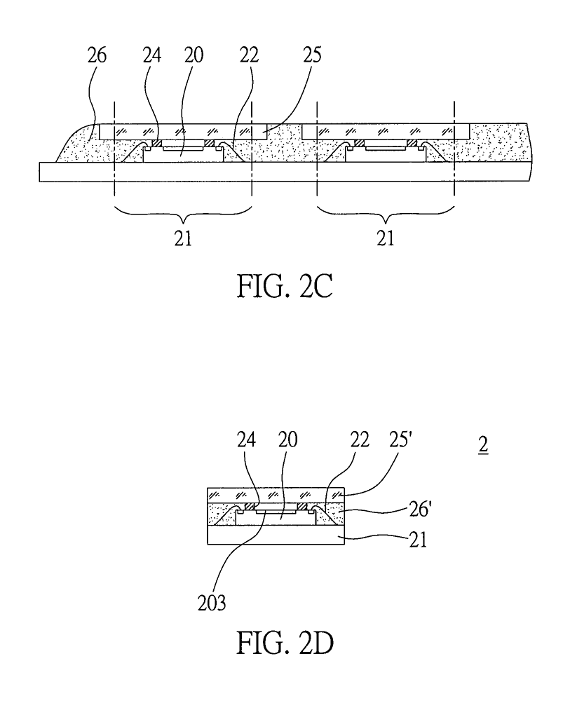

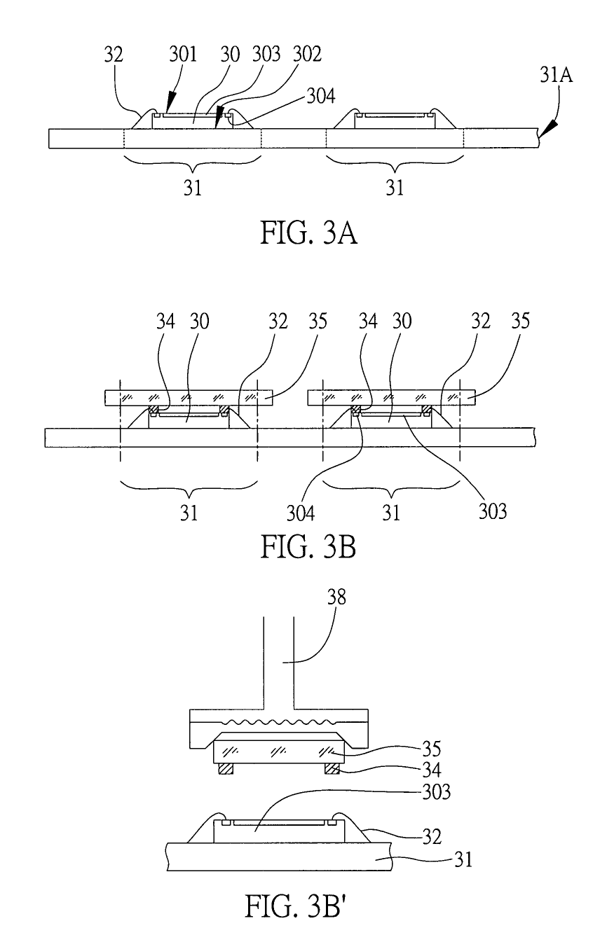

FIGS. 3A to 3D show a sensor-type semiconductor package and a fabrication method thereof according to a second embodiment of the present invention. The main difference between the present embodiment and the first embodiment is that the adhesive layer of the second embodiment is heated to a melting state so as to directly cover all over the end portions of the bonding wires, which is connected to the sensor type chip, thus, after the adhesive layer is solidified, the light-permeable body can be configured to cover and seal the sensor area, thereby eliminating the need of keeping certain distance, which is generally bigger than 300 μm, between the sensor area 203 and the electrode pads 24 of the sensor chip 20 for disposing of the adhesive layer 24 in the first embodiment (as shown in FIGS. 2A-2D). As a result, size of the sensor chip and the sensor-type semiconductor package can be reduced through the present embodiment and meanwhile design flexibility of the sensor chip is increased.

As shown in FIG. 3A, a module 31A having a plurality of chip carriers 31 is provided and the sensor chips 30 are attached on the chip carriers 31.

Each sensor chip 30 has an active surface 301 and a non-active surface 302 opposed to the active surface 301, and the active surface 301 has a sensor area 303 and a plurality of electrode pads 304 formed thereon. The sensor chip 30 is attached to the chip carrier 31 through its non-active surface 302, and the electrode pads 304 of the sensor chip 30 are connected to the chip carrier 31 via a plurality of bonding wires 32 for electrically coupling the sensor chip 30 and the chip carrier 31.

As shown in FIG. 3B, the light-permeable bodies 35 are mounted on the sensor chips 30 through an adhesive layers 34 formed on the light-permeable bodies 35, and the adhesive layers 34 covering all over the end portions of the plurality of bonding wires 32 electrically connected to the corresponding sensor chip 30. The planar size of the light-permeable body 25 is larger than the predefined planar size of the sensor-type semiconductor package to be formed (as defined between the dashed lines).

When mounting the light-permeable bodies 35 to the sensor chips 30, the light-permeable bodies 35 are heated and a heating source is provided below the chip carriers 31 so as to melt the adhesive layers 34, and after the melted adhesive layers 34 contact the plurality of bonding wires 32 and covers all over the end portions of the plurality of bonding wires 32, the heating source is removed away. As a result, the adhesive layers 34 are solidified and the light-permeable bodies 35 can be supported by the solidified adhesive layers 34.

The adhesive layers 34 may be made of a B-stage epoxy resin formed on the light-permeable bodies 35. After the light-permeable bodies 35 are heated, the adhesive layers 34 enter a half-melting state and have adhesiveness. Accordingly, the light-permeable bodies 35 can be mounted to the sensor chips 30 at positions corresponding to the electrode pads 304 through the adhesive layers 34 and meanwhile, the end portions of the plurality of bonding wires 32 connected to the sensor chips 30 are covered by the adhesive layers 34.

As shown in FIG. 3B′, a mechanical arm 38 having heating function can be used to clip and heat the light-permeable body 35 so as to melt the adhesive layer 34 on the surface of the light-permeable body 35. The melted adhesive layer 34 further covering all over the end portions of the plurality of bonding wires 32 connected to the sensor chip 30. Thereafter, the mechanical arm 38 and the heating source are removed away and the adhesive layer 34 is cooled and solidified.

As shown in FIG. 3C, an encapsulating process is performed for forming an encapsulant 36 on the chip carriers 31, wherein the encapsulant 36 encapsulates the sensor chips 30 and the plurality of bonding wires 32. Meanwhile, the upper surfaces of the light-permeable bodies 35 are exposed from the encapsulant 36.

As shown in FIG. 3D, the cutting according to the predefined planar size is performed. As the planar size of each light-permeable body 35 is larger than the predefined planar size of the semiconductor package 3, to obtain a desired sensor-type semiconductor package 3, the cutting path will pass through the light-permeable body 35, the encapsulant 36 and the chip carrier 31. Through the cutting process, the cut light-permeable body 35′ has the same planar size as the obtained sensor-type semiconductor package 3.

Through the above fabrication method, the present invention also discloses the sensor-type semiconductor package 3 (as shown in FIG. 3D), which comprises: the chip carrier 31; the sensor chip 30 attached to the chip carrier 31 and electrically connected with the chip carrier 31 through the plurality of bonding wires 32; the light-permeable body 35 mounted on the sensor chip 30 with the adhesive layer 34 as a partition therebetween, wherein the adhesive layer 34 covering all over the end portions of the plurality of bonding wires 32 connected to the sensor chip 30; and the encapsulant 36 formed between the chip carrier 31 and the light-permeable body 35 for encapsulating the sensor chip 30 and the bonding wires 32, wherein the upper surface of the light-permeable body 35 is exposed from the encapsulant 36 and the planar size of the cut light-permeable body 35′ is the same as the planar size of the sensor-type semiconductor package 3.

### Third Embodiment

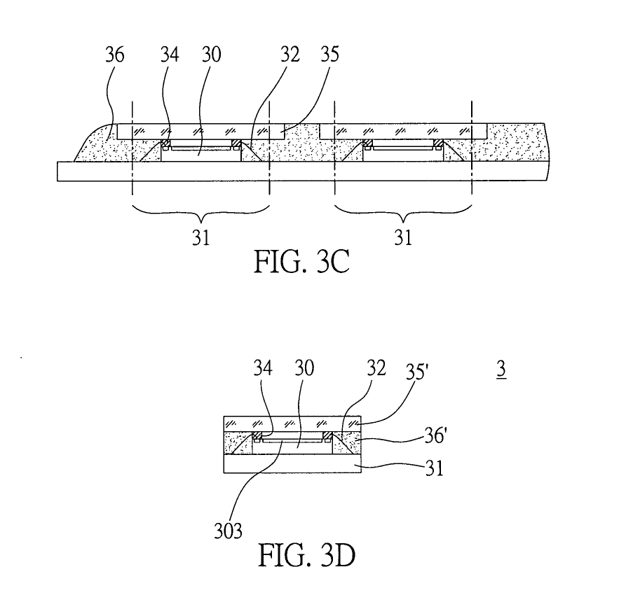

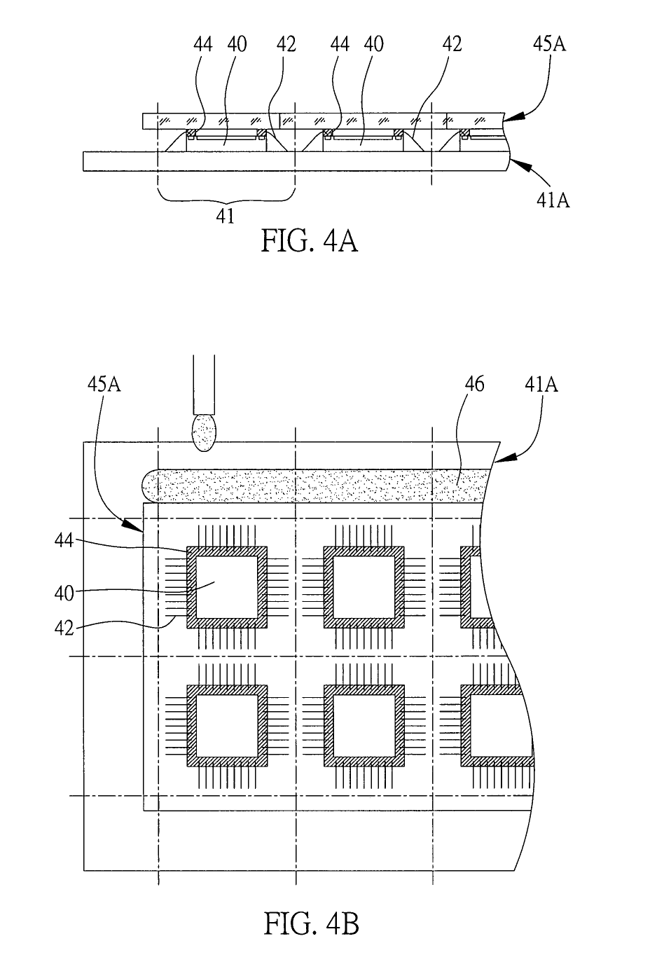

FIGS. 4A and 4B are schematic diagrams showing a fabrication method of a sensor-type semiconductor package according to a third embodiment of the present invention. The semiconductor package 4 is similar to those of the above-mentioned embodiments. For simplifying the description and drawings, the similar parts between the present embodiment and the above-mentioned embodiments are omitted. In the present embodiment, the sensor chips 40 attached to the chip carriers 41 of the module 41A are covered by a light-permeable body 45A such as a whole piece of glass, wherein peripheral size of the light-permeable body 45A is larger than the predefined cutting lines of the sensor-type semiconductor packages (as defined by the two adjacent dashed lines). The light-permeable body 45A has a plurality of adhesive layers 44 corresponding in position to the sensor chips 40, and each adhesive layer 44 covers all over the end portions of the plurality of bonding wires 42 electrically connected to the sensor chip 40.

As shown in FIG. 4B, a dispensing method is used such that an encapsulant 46 can be filled between the module 41A and the light-permeable body 45A for encapsulating the sensor chips 40 and the bonding wires 42. Then, the cutting can be performed by cutting through the light-permeable body 45A, the encapsulant 46 and the module 41A according to the predefined planar size of the sensor-type semiconductor package so as to obtain a plurality of sensor-type semiconductor packages. For each sensor-type semiconductor package, the cut light-permeable body has the same planar size as the sensor-type semiconductor package.

Further referring to FIG. 4B′, instead of using a dispensing method, the module 41A is disposed in a mold cavity 470 of a mold 47 with the top surface of the light-permeable body 45A abutting against the top portion of the mold cavity 470. By injecting the encapsulating material into the mold cavity 470, an encapsulant 46 encapsulating the sensor chip 40 and the bonding wires 42 can be formed.

### Fourth Embodiment

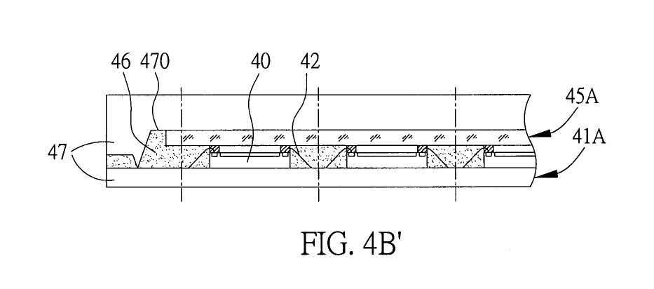

FIGS. 5A to 5C are schematic cross-sectional diagrams showing a fabrication method of a sensor-type semiconductor package according to a fourth embodiment of the present invention. According to the above-described embodiments, the planar size of the light-permeable body is larger than the predefined planar size of the sensor-type semiconductor package and accordingly the cutting path passes through the light-permeable body. To prevent the light-permeable body made of such as glass from cracking and avoid wearing of the cutting tools during the cutting, the present embodiment performs a bevel cut to the light-permeable body so as to form bevel edges on the side surfaces of the light-permeable body before cutting the package according to the predefined planar size.

As shown in FIGS. 5A and 5B, after the encapsulating process is performed, the light-permeable bodies 55 are bevel cut along the cutting paths according to the predefined planar size so as to form bevel edges 550 on the side surfaces of the light-permeable bodies 55.

As shown in FIG. 5C, a second cutting process is performed at positions of bevel edges 550 of the light-permeable bodies 55 according to the predefined planar size of the sensor-type semiconductor package 5 so as to separate the chip carriers 51 from each other. Thus, a plurality of sensor-type semiconductor packages 5 are obtained, wherein, bevel edges 550 are formed at the side surfaces of the light-permeable bodies 55. The present embodiment can prevent the light-permeable bodies from cracking during the cutting process and increase lifetime of the cutting tools.

### Fifth Embodiment

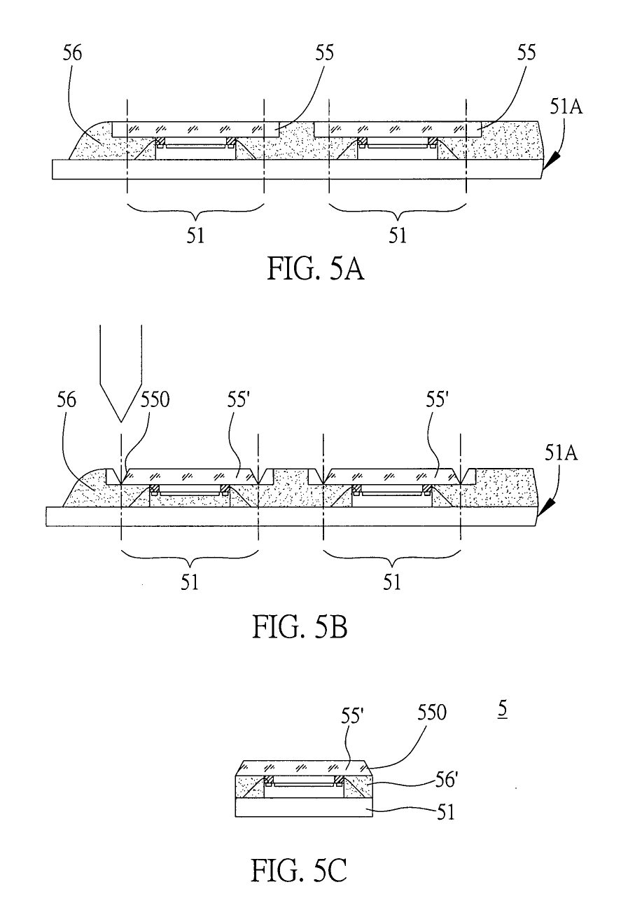

FIG. 6 is a schematic cross-sectional diagram of a sensor-type semiconductor package according to a fifth embodiment of the present invention. The semiconductor package 6 is similar to those of the above-mentioned embodiments. For simplifying the description and drawings, the similar parts between the present embodiment and the above-mentioned embodiments are omitted. In the present embodiment, to increase the bonding between the light-permeable body 65 and the encapsulant 66 as well as the bonding between the light-permeable body 65 and the adhesive layer 64, a rough structure 651 is formed on the surface of the light-permeable body 65 at positions corresponding to the encapsulant 66 and the adhesive layer 64, thus preventing cracks from occurring between the light-permeable body 65 and the encapsulant 66 as well as between the light-permeable body 65 and the adhesive layer 64 and further preventing external particles from contaminating the sensor chip.

### Sixth Embodiment

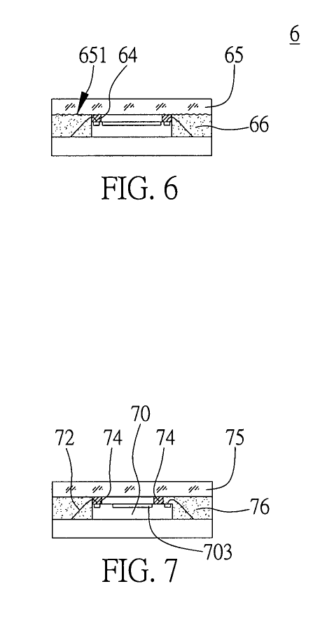

FIG. 7 is a schematic cross-sectional diagram of a sensor-type semiconductor package according to a sixth embodiment of the present invention. Different from the previous embodiments, the adhesive layer 74 as the partition between the light-permeable body 75 and the sensor chip 70 only partially covers the end portions 72 connected to the sensor chip 70 for increasing the flexibility in the design of the size of the sensor chip 70 and the light-permeable body 75.

Therefore, the sensor-type semiconductor package and the fabrication method thereof of the present invention mainly includes attaching a sensor chip to a chip carrier and electrically connecting the sensor chip to the chip carrier via a plurality of bonding wires, mounting a light-permeable body having an adhesive layer formed thereunder to the sensor chip, proceeding with a subsequent encapsulating process and a cutting process. As the initial planar size of the light-permeable body is larger than the predefined planar size of the sensor-type semiconductor package to be formed, the encapsulant can be completely formed between the chip carrier and the light-permeable body, that is, contacting area between the light-permeable body and the encapsulant is maximized. Thus, after cutting according to the predefined planar size, the light-permeable body and the encapsulant are completely adhered with each other. With the help of the rough structure formed on the light-permeable body at positions corresponding to the encapsulant, the bonding of the light-permeable body can further be reinforced so as to prevent external moisture or particles from entering the package and adversely affecting lifetime of the products.

Furthermore, the adhesive layer can be disposed between the sensor area and the electrode pads of the sensor chip. Alternatively, the adhesive layer can be heated to a melting state for being disposed on the electrode pads, and for covering the end portions of the plurality of bonding wires connected to the sensor chip. And after the adhesive layer is solidified, the sensor area is covered and sealed by the light-permeable body. Such a method can reduce sizes of the sensor chip and the sensor-type semiconductor package, increase chip production, decrease chip cost and increase the design flexibility of the sensor chip.

The above descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A fabrication method of a sensor-type semiconductor package, comprising steps of:
attaching a sensor chip to a chip carrier and electrically connecting the sensor chip with the chip carrier via a plurality of bonding wires;
mounting a light-permeable body to the sensor chip with an adhesive layer as a partition therebetween, wherein a planar size of the light-permeable body is larger than a predefined planar size of the sensor-type semiconductor package to be formed;
forming an encapsulant on the chip carrier for encapsulating the sensor chip and the plurality of bonding wires with an upper surface of the light-permeable body being exposed from the encapsulant; and
cutting through the light-permeable body, the encapsulant and the chip carrier according to the predefined planar size of the sensor-type semiconductor package so that the cut light-permeable body and the sensor-type semiconductor package have the same planar size.

2. The fabrication method of claim 1, wherein the sensor-type semiconductor package is fabricated in a batch-type process, comprising steps of providing a module having a plurality of chip carriers, attaching a plurality of sensor chips to the respective chip carriers, mounting a light-permeable body to each of the plurality of sensor chip, encapsulating the plurality of chip carriers and performing a cutting process so as to obtain a plurality of the sensor-type semiconductor packages.

3. The fabrication method of claim 2, wherein the light-permeable body is a whole piece of glass having a plurality of adhesive layers formed thereon, and the plurality of adhesive layers are positioned corresponding to the sensor chips.

4. The fabrication method of claim 1, wherein the encapsulant is filled between the chip carrier and the light-permeable body by dispensing so as to encapsulate the sensor chip and the plurality of bonding wires.

5. The fabrication method of claim 1, further comprising steps of: disposing the chip carrier in a mold cavity of a mold with the upper surface of the light-permeable body abutting against an top of the mold cavity; and injecting an encapsulating material into the mold cavity so as to form the encapsulate encapsulating the sensor chip and the plurality of bonding wires on the chip carrier.

6. The fabrication method of claim 1, wherein the sensor chip has an active surface and a non-active surface opposed to the active surface, a sensor area and a plurality of electrode pads are formed on the active surface of the sensor chip, the non-active surface of the sensor chip is attached to the chip carrier and the sensor chip is electrically connected with the chip carrier via the plurality of bonding wires connected to the electrode pads of the sensor chip.

7. The fabrication method of claim 6, wherein the adhesive layer is disposed between the sensor area and the electrode pads of the sensor chip so as to enclose and seal the sensor area.

8. The fabrication method of claim 6, wherein, the non-active surface of the sensor chip is thinned and the sensor chip is a selected before being attached to the chip carrier

9. The fabrication method of claim 1, wherein the cutting step further comprises steps of bevel cutting the light-permeable body according to the predefined planar size of the sensor-type semiconductor package to form bevel edges on the light-permeable body; and cutting from the bevel edges so as to obtain a sensor-type semiconductor package having bevel edges formed on the sides of the cut light-permeable body.

10. The fabrication method of claim 1, further comprising forming a rough structure on a side of the light-permeable body, wherein the side is contacted with the adhesive layer and the encapsulant.

11. A fabrication method of a sensor-type semiconductor package, comprising steps of:
attaching a sensor chip to a chip carrier and electrically connecting the sensor chip with the chip carrier via a plurality of bonding wires;
mounting a light-permeable body to the sensor chip with an adhesive layer as a partition therebetween, wherein the adhesive layer covers end portions of the plurality of bonding wires connected to the sensor chip and a planar size of the light-permeable body is larger than a predefined planar size of the sensor-type semiconductor package to be formed;
forming an encapsulant on the chip carrier for encapsulating the sensor chip and the plurality of bonding wires with an upper surface of the light-permeable body being exposed from the encapsulant; and
cutting through the light-permeable body, the encapsulant and the chip carrier according to the predefined planar size of the sensor-type semiconductor package so that the cut light-permeable body and the sensor-type semiconductor package have the same planar size.

12. The fabrication method of claim 11, the step of mounting the light-permeable body to the sensor chip further comprises steps of heating the light-permeable body with a heating source provided below the chip carrier so as to melt the adhesive layer; and removing the heating source form the chip carrier for solidifying the adhesive layer after the melted adhesive layer contacts the plurality of bonding wires and covers the end portions of the plurality of bonding wires.

13. The fabrication method of claim 11, wherein the adhesive layer is made of a B-stage epoxy resin, and it enters a half-melting state and has an adhesive property when the light-permeable body is heated, thereby the light-permeable body is mounted to the sensor chip and the adhesive layer covering the end portions of the plurality of bonding wires connected to the sensor chip.

14. The fabrication method of claim 11, further comprising steps of clipping the light-permeable body by a mechanical arm having a heating function; providing a heating source to heat the adhesive layer disposed on a lower surface of the light-permeable body to a melting state such that the end portions of the plurality of bonding wires can be covered by the adhesive layer at the melting state; and removing the mechanical arm and the heating source for solidifying the adhesive layer.

15. The fabrication method of claim 11, wherein the adhesive layer partially covers the end portions of the bonding wires connected to the sensor chip.

16. A sensor-type semiconductor package, comprising:
a chip carrier;
a sensor chip mounted on the chip carrier and electrically connected with the chip carrier via a plurality of bonding wires;
a light-permeable body mounted on the sensor chip through an adhesive layer; and
an encapsulant formed between the chip carrier and the light-permeable body for encapsulating the sensor chip and the plurality of bonding wires with an upper surface of the light-permeable body being exposed from the encapsulant, wherein a planar size of the light-permeable body is the same as a planar size of the formed sensor-type semiconductor package.

17. The sensor-type semiconductor package of claim 16, wherein end portions of the plurality of bonding wires connected to the sensor chip are partially covered by the adhesive layer.

18. The sensor-type semiconductor package of claim 16, wherein the encapsulant is filled between the chip carrier and the light-permeable body by dispensing so as to encapsulate the sensor chip and the bonding wires.

19. The sensor-type semiconductor package of claim 16, wherein the chip carrier is disposed in a mold cavity of a mold with the upper surface of the light-permeable body abutting against a top of the mold cavity, then an encapsulating material is injected into the mold cavity to form the encapsulate encapsulating the sensor chip and the plurality of bonding wires on the chip carrier.

20. The sensor-type semiconductor package of claim 16, wherein the sensor chip has an active surface and a non-active surface opposed to the active surface, a sensor area and a plurality of electrode pads formed on the active surface of the sensor chip, the non-active surface of the sensor chip is attached to the chip carrier, and the sensor chip is electrically connected with the chip carrier via the plurality of bonding wires connected to the electrode pads of the sensor chip.

21. The sensor-type semiconductor package of claim 20, wherein the adhesive layer serves as a partition between the light-permeable body and the sensor chip, and is disposed between the sensor area and the plurality of electrode pads of the sensor chip so as to enclose and seal the sensor area.

22. The sensor-type semiconductor package of claim 16, wherein the light-permeable body has bevel edges formed on sides thereof.

23. The sensor-type semiconductor package of claim 16, wherein the light-permeable body further comprises a rough structure formed on a side thereof and to be contacted with the adhesive layer and the encapsulant.
